(19) United States
(12) Patent Application Publication
(10) Pub. No.: US 2007/0274041 A1
(43) Pub. Date: Nov. 29, 2007

(54) METHOD OF ACCELERATING HEAT DISSIPATION FOR A COMPACT ELECTRONIC DEVICE BY EXTRACTING AIR

(75) Inventors: Keng-Wen TSENG, Jhonghe City (TW); I-Cheng YUAN, Sinjhuang City (TW); Chi-Wei WANG, Sinjhuang City (TW)

Correspondence Address: PATENTTM.US, P. O. BOX 82788, PORTLAND, OR, 97282-0788, US

(73) Assignee: SIMPLE TECH CO., LTD., Keelung City (TW)

(21) Appl. No.: 11/749,643

(22) Filed: May 16, 2007

(30) Foreign Application Priority Data
May 23, 2006 (TW) 095118251

(51) Int. Cl. H05K 7/20

(52) U.S. Cl. 361/695; 361/687

(57) ABSTRACT

A method of accelerating heat dissipation for a compact electronic device has steps of defining a heat dissipation opening as an airflow emission opening on a compact electronic device; defining connection port and slot as intake openings on the compact electronic; and extracting air from the airflow emission opening to make cold air effectively enter the intake openings. Therefore, the cold air thoroughly passes multiple heating elements and then to go out via the airflow emission opening. In this way, to force convection is achieved, so as to enhance cooling efficiency.

### BACKGROUND OF THE INVENTION

1. Field of the Invention

The invention relates in general to a method of accelerating heat dissipation for a compact electronic device, and more particularly to a method of accelerating heat dissipation for a compact electronic device by air extracting air.

2. Description of the Related Art

Along with the development of a notebook computer and a barebone computer to provide more powerful computers with light, thin, short and small-sized design than the conventional personal, the CPU (central processing unit), GPU (graphic processing unit) and memory of producing heat of high power electronic elements have to be compacted in a small space. The small space usually can not have good air convection to exchange current with the external air. The heat is easily kept inside the small space. However, the accumulated heat inside the small space without good current circulation may cause damage to the electronic elements, and even worse to burn down the electronic elements.

The conventional heat dissipation methods for the compact electronic device are mostly to provide a small fan inside the small space. Then the fan brings external cold air into the small space to cool down the internal electronic elements. Hence the heat inside the small space is exhausted. However, since the small space only can afford small-sized fan, a wind force of the fan is very limited. In addition, when the electronic device operates for a long time, the performance of electronic device goes down and even the machine crashes due to overheating problem.

Moreover, a heat pipe is used to couple between the electronic elements and a metal diversion cover of the electronic device. The heat of the electronic elements can be conducted to the metal diversion cover to be exhausted. However, an efficiency of this passive heat dissipation method is poor and also this method only can be applied to low-power consumption electronic elements.

### SUMMARY OF THE INVENTION

An objective of the present invention is to provide a method of accelerating heat dissipation for a compact electronic device by extracting air.

In order to achieve the above objective, the method has steps of.

defining a heat dissipation opening as an airflow emission opening on a compact electronic device;

defining connection port and slot as intake openings on the compact electronic; and

extracting air from the airflow emission opening to make cold air effectively enter the intake openings.

Therefore, the cold air thoroughly passes multiple heating elements and then to go out via the airflow emission opening. In this way, to force convection is achieved, so as to enhance cooling efficiency. Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a preferred embodiment of an air-extracting fan apparatus in accordance with the present invention;

FIG. 2 is a perspective view of the air-extracting fan apparatus coupled to a compact electronic device;

FIG. 3 is an exploded view of the air-extracting fan apparatus in accordance with the present invention; and

FIG. 4 is a temperature-time curve diagram of internal elements of the compact electronic device when the air-extracting fan apparatus of the present invention coupled to the compact electronic device.

### DETAILED DESCRIPTION OF THE INVENTION

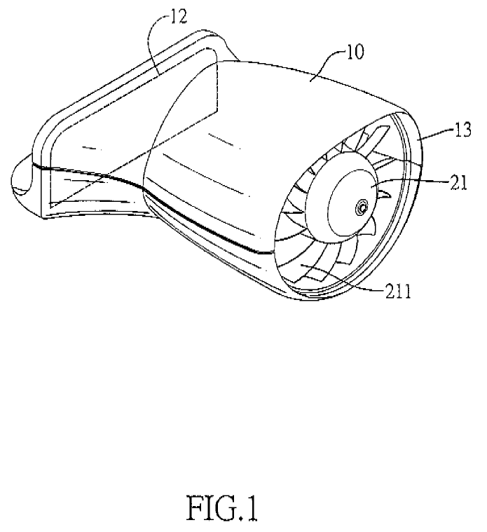

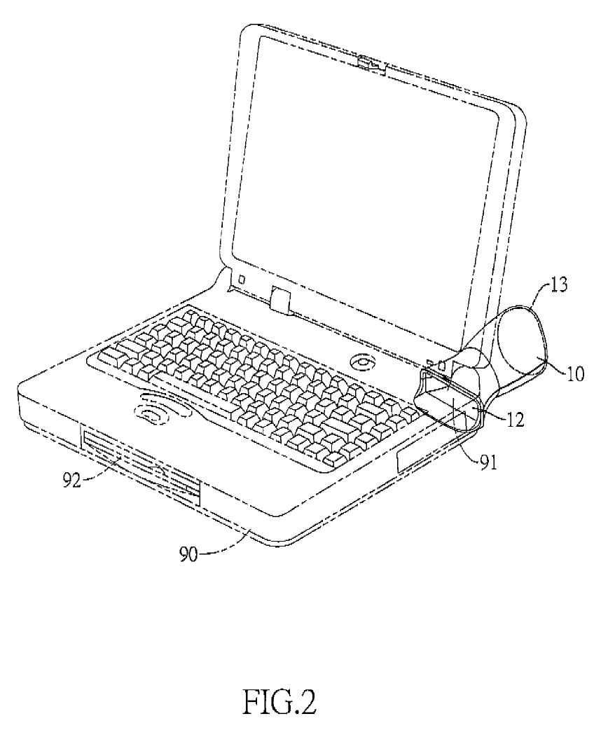

With reference to FIG. 1 and FIG. 2, a preferred embodiment of a method of accelerating heat dissipation in accordance with the present invention has steps of:

defining at least one heat dissipation opening 91 as an airflow emission opening on a compact electronic device 90;

defining multiple intake openings 92 on the compact electronic device 90 including a connection port and a slot and the like; and

extracting air from the airflow emission opening to make cold air effectively enter the intake openings 92 of the compact electronic device 90. Therefore, the cold air thoroughly passes multiple heating elements of the compact electronic device 90 and then to go out via the airflow emission opening. In this way, an objective to force convection can be achieved, so to enhance cooling efficiency.

In the step of extracting air has further acts of:

attaching an air-extracting fan apparatus to the airflow emission opening 91; and

starting the air-extracting fan apparatus to extract air from the heat dissipation opening 91 of the compact electronic device 90.

In this way, external current is accelerated to enter inside the compact electronic device 90 via the intake openings 92 of the connection port and then the current passes through the heat dissipation opening 91 and the air-extracting fan apparatus.

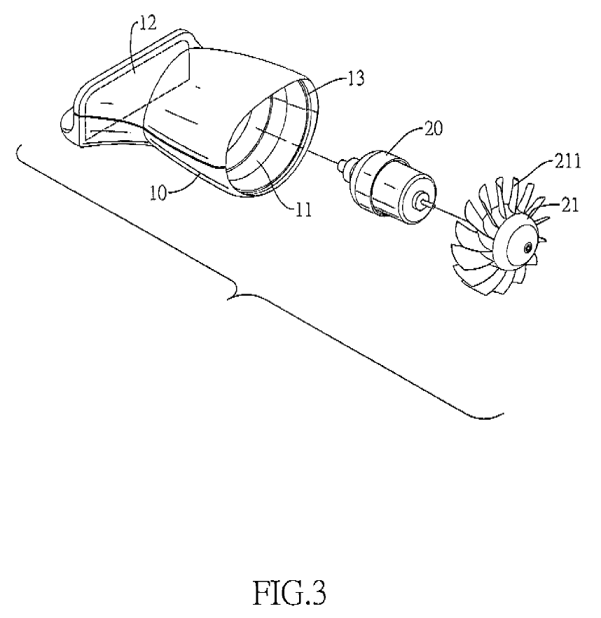

With reference to FIG. 3, the air-extracting fan apparatus further includes a diversion cover 10 and a fan module.

The diversion cover 10 has an inlet opening 12, an air vent 13 and a chamber 11. The inlet opening 12 is attached to the heat dissipation opening 91 of the compact electronic device 90. The chamber 11 is communicated with the inlet opening 12 and the air vent 13 and forming a progressively enlarged along a direction from the inlet opening 12 toward the air vent 13. Moreover, the diversion cover 10 is made up by flexible material such as rubber material, so as to make the inlet opening 12 attached to the heat dissipation opening 91 of the compact electronic device 90 tightly.

The fan module is configured inside the diversion cover 10 and includes a motor 20 and a moving fan blade set. The moving fan blade set has a hub 21 and multiple blade parts 211 radial extended from the hub 21. The hub of the moving fan blade is pivoted coupled on the motor 20. The motor 20 drives the moving fan blade to rotate.

The moving fan blade 21 starts to rotate to extract the air inside the heat dissipation opening 91 when the fan module 20 operates. Hence a built-in fan efficiency of the compact electronic device 90 can be enhanced. The external current enters the compact electronic device 90 via the intake openings 92 of the connection port and the slot, so as to accelerate heat exchange of the external current and the internal electronic elements. Finally the air is exhausted via the air vent 13 of the air-extracting fan apparatus. In this way, an internal temperature of the compact electronic device 90 can be efficiently cooling down; so as to make the compact electronic device 90 operate normally.

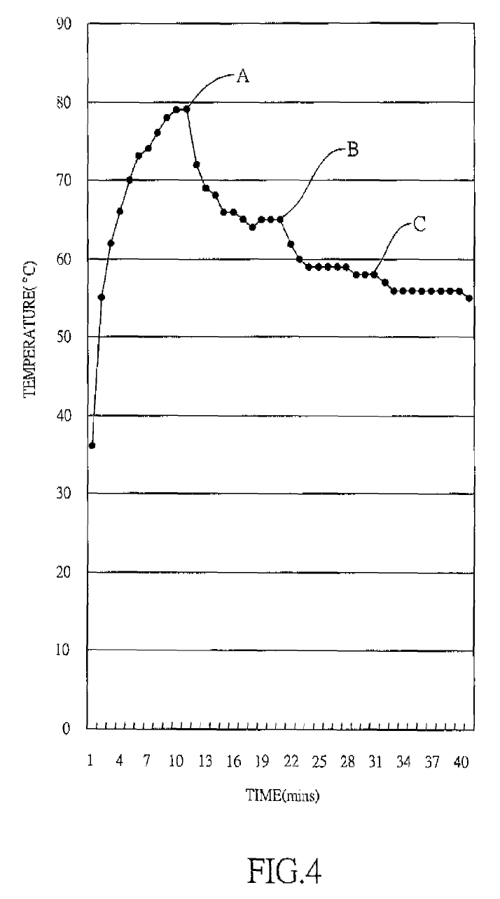

With reference to FIG. 4, a temperature-time curve diagram of the internal elements of the compact electronic device 90 is shown.

Firstly, when a computer boots to perform software, the computer fully operates to make performance achieve 100%. At this moment, the built-in fan apparatus of the compact electronic device 90 dissipates heat of the internal element. The internal element is a CPU (central processing unit) for example.

Secondly, a coordinate location A is achieved after ten minutes. At this moment, a temperature of the CPU achieves 78° C. while a rotation rate of the built-in fan is 5100 RPM.

Thirdly, the air-extracting fan apparatus is enabled to make the moving fan blade 21 extract the air with the rotation rate of 2300 RPM. Then a coordinate location B is achieved after another ten minutes. At this moment, the CPU is cooling down to 64° C.

Fourthly, the rotation rate of the moving fan blade 21 is increased to achieve 3300 RPM. After ten minutes, the CPU is cooling down to 58° C. as a coordinate location C.

Fifthly, the rotation rate of the moving fan blade 21 is further increased to achieve 3800 RPM. After ten minutes, the CPU is further cooling down to 55° C.

Therefore, it can be understood that with the air-extracting fan apparatus of the present invention, the temperature of the CPU can be cooling down for 23 degrees by the fan blade rotation rate of only 3800 RPM. The heat dissipation efficiency of the air-extracting fan apparatus is indeed very excellent.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of accelerating beat dissipation for a compact electronic device by extracting air comprising steps of:
defining at least one heat dissipation opening as an airflow emission opening on a compact electronic device;
defining a plurality of intake openings on the compact electronic device; and
extracting air from the airflow emission opening to make cold air effectively enter inside the intake openings of the compact electronic device, whereby the cold air thoroughly passes multiple heating elements of the compact electronic device and then to go out via the airflow emission opening to force convection to enhance cooling efficiency.

2. The method as claimed in claim 1, wherein the step of extracting air comprises acts of:
attaching an air-extracting fan apparatus to the airflow emission opening; and
starting the air-extracting fan apparatus to extract air from the heat dissipation opening of the compact electronic device.

3. The method as claimed in claim 2, wherein the air-extracting fan apparatus comprises:
a diversion cover having
an inlet opening attached to the heat dissipation opening of the compact electronic device;
an air vent; and
a chamber communicated with the inlet opening and the air vent and forming a progressively enlarged along a direction from the inlet opening toward the air vent; and
a fan module configured inside the diversion cover and comprising
a motor; and
a moving fan blade having
a hub pivoted coupled on the motor; and
multiple blade parts radial extended from the hub 21.

4. The method as claimed in claim 3, wherein the diversion cover is made of flexible material.

5. The method as claimed in claim 1, wherein the plurality of intake openings is a connection port and a slot on the compact electronic.
